(19) United States
(12) Patent Application Publication
(10) Pub. No.: US 2015/0123518 A1
(43) Pub. Date: May 7, 2015

(54) MEMBER INCLUDING MULTILAYER THIN FILM, METHOD OF MANUFACTURING THE SAME, AND ELECTRONIC PRODUCT INCLUDING THE SAME

(71) Applicant: SAMSUNG ELECTRONICS CO., LTD., Suwon-si (KR)

(72) Inventors: Seo Joon LEE, Suwon-si (KR); Jin Sub KIM, Yongin-si (KR); Hyong Jun YOO, Hwaseong-si (KR); Min Chul JUNG, Pyeongtaek-si (KR); Jin Hyun CHO, Seoul (KR)

(73) Assignee: SAMSUNG ELECTRONICS CO., LTD., Suwon-si (KR)

(21) Appl. No.: 14/529,972

(22) Filed: Oct. 31, 2014

(30) Foreign Application Priority Data
Nov. 1, 2013 (KR) 10-2013-0131917
Nov. 6, 2013 (KR) 10-2013-0134059
Jul. 30, 2014 (KR) 10-2014-0097123

(51) Int. Cl. H05K 5/04; B05D 1/36; B05D 5/06; B05D 3/06

(52) U.S. Cl. CPC H05K 5/04; B05D 3/068; B05D 1/36; B05D 5/06; B05D 5/063
USPC 312/223.1; 427/535; 428/450; 428/457; 428/472; 428/421

(57) ABSTRACT

A plastic member, on which a metal layer is formed on a surface of a plastic object, a method of manufacturing the same, and an electronic product including the same are provided. The method of manufacturing a multilayer thin film includes modifying a surface of a plastic object using a plasma treatment, depositing a reflective metal layer on the surface of the plastic object, and depositing a transparent ceramic layer on the reflective metal layer.

### CROSS-REFERENCE TO RELATED APPLICATIONS

This application claims priority from Korean Patent Application Nos. 10-2013-0131917, 10-2013-0134059, and 10-2014-0097123 filed on Nov. 1, 2013, Nov. 6, 2013, and Jul. 30, 2014, respectively, in the Korean Intellectual Property Office, the disclosures of which are incorporated herein by reference in their entireties.

### BACKGROUND

1. Field

Apparatuses and methods consistent with exemplary embodiments relate to a method of implementing a metal sense on an exterior of a product, and more particularly, to a method of depositing a multilayer thin film on a surface of a plastic object having a planar shape or a curved shape so that a deep metal sense is implemented on an exterior of a product.

2. Description of the Related Art

A plastic material may be lighter, may have additional shape flexibility as compared to a metal, and may allow for a complex shape to be manufactured at a low price. In recent years, many efforts have been put forth to implement a plastic base material on an exterior of a product such that the plastic base material has a metal sense.

A plating method, a hot stamping method, a general coating method, and the like may be used in order to implement the metal sense on the plastic base material. For example, some particular methods that may be used include a method of coating a thin film of a metallic paint, a method of coating using a translucent resin, and the like.

Because it is difficult to provide a translucent sense when a coating film becomes thicker when implementing a translucent metal sense on an injection molded material using a commonly used coating method, a translucent color may be created by mixing paints, and a transparent paint may be separately used.

In addition, a technique in which a translucent plastic product is manufactured by adding a color to a transparent resin has been implemented. However, the technique provides no deep sense of a metal thin film and the same color is shown at all angles. A method of implementing a gradient effect by changing a thickness of a transparent injection molding material is also possible. However, this method also has a limit to providing a metal sense.

### SUMMARY

One or more exemplary embodiments provide a plastic member, in which a metal layer is formed on a surface of a plastic object, a method of manufacturing the same, and an electronic product including the same.

Specifically, one or more exemplary embodiments provide a plastic member, in which a metal layer is formed on a surface of a plastic object having a planar shape or a curved shape, a method of manufacturing the same, and an electronic product including the same.

Further, one or more exemplary embodiments provide a plastic member, in which a first metal layer and a second metal layer having a refractive index smaller than the first metal layer are formed to implement a deep metal sense, a method of manufacturing the same, and an electronic product including the same.

According to an aspect of an exemplary embodiment, there is provided a method of manufacturing a multilayer thin film, the method including plasma-treating a surface of a plastic object, depositing a reflective metal layer on the surface of the plastic object, and depositing a transparent ceramic layer on the reflective metal layer.

The depositing the reflective metal layer on the surface of the plastic object may include providing a target sample including at least one selected from a group consisting of gold (Au), silver (Ag), aluminum (Al), chromium (Cr), titanium (Ti), and Tin (Sn) in a multilayer thin film manufacturing device, and applying power from a power source to the multilayer thin film manufacturing device.

The depositing the transparent ceramic layer on the reflective metal layer may include providing a target sample including at least one selected from a group consisting of aluminum (Al), chromium (Cr), titanium (Ti), and silicon (Si) in a multilayer thin film manufacturing device, injecting a reaction gas including nitrogen (N2) and oxygen (O2) in the multilayer thin film manufacturing device, and applying power from a power source to the multilayer thin film manufacturing device and reacting the target sample with the reaction gas.

The method may further include, after the plasma-treating the surface of the plastic object, depositing a hardness enhancement layer on the plastic object.

The depositing the hardness enhancement layer may include depositing a first hardness enhancement layer including chromium (Cr) on the plastic object, and depositing a second hardness enhancement layer including at least one selected from a group consisting of titanium nitride (TiN), chromium nitride (CrN), and aluminum nitride (AlN) on the first hardness enhancement layer.

According to an aspect of another exemplary embodiment, there is provided a method of manufacturing a multilayer thin film, the method including modifying a surface of a plastic object using a plasma treatment, depositing a first metal layer on the surface of the plastic object, and depositing a second metal layer on the first metal layer, wherein the second metal layer has a refractive index that is smaller than a refractive index of the first metal layer.

The depositing the first metal layer on the surface of the plastic object may include providing a metallic material including at least one component selected from a group consisting of aluminum (Al), chromium (Cr), titanium (Ti), and silicon (Si) in a multilayer thin film manufacturing device, injecting at least one reaction gas selected from a group consisting of nitrogen (N2) and oxygen (O2) in the multilayer thin film manufacturing device, and applying power from a power source to the multilayer thin film manufacturing device and reacting the metallic material with the reaction gas.

The power source may include at least one of a pulsed DC power source and a DC power source.

The depositing the second metal layer on the first metal layer may include providing a metallic material including at least one selected from a group consisting of aluminum (Al), chromium (Cr), titanium (Ti), and silicon (Si) in a multilayer thin film manufacturing device, and applying power from a power source to the multilayer thin film manufacturing device.

The power source may include at least one of a pulsed DC power source and a DC power source.

The method may further include depositing an adhesive layer on the surface of the plastic object after the modifying the surface of the plastic object using the plasma treatment, and before the depositing the first metal layer.

The method may further include depositing a protective layer on the second metal layer after the depositing the second metal layer on the first metal layer.

According to an aspect of another exemplary embodiment, there is provided a plastic member including a plastic object, a reflective metal layer coupled to the plastic object, and a transparent ceramic layer coupled to the reflective metal layer.

The reflective metal layer may include at least one selected from a group consisting of gold (Au), silver (Ag), aluminum (Al), chromium (Cr), titanium (Ti), and Tin (Sn).

The transparent ceramic layer may include at least one selected from a group consisting of aluminum nitride (AlN), chromium nitride (CrN), titanium nitride (TiN), silicon nitride (Si3N4), aluminum oxide (Al2O3), chromium oxide (Cr2O3), titanium oxide (Ti2O3), and silicon oxide (SiO2).

The plastic member may further include a hardness enhancement layer interposed between the plastic object and the reflective metal layer.

The hardness enhancement layer may include a first hardness enhancement layer including chromium (Cr) and coupled to the plastic object, and a second hardness enhancement layer including at least one selected from a group consisting of titanium nitride (TiN), chromium nitride (CrN), and aluminum nitride (AlN) and coupled to the first hardness enhancement layer.

According to an aspect of another exemplary embodiment, there is provided a plastic member including a plastic object which is plasma treated, a first metal layer deposited on the plastic object, and a second metal layer deposited on the first metal layer and having a refractive index that is smaller than a refractive index of the first metal layer.

The first metal layer may include at least one selected from a group consisting of aluminum nitride (AlN), chromium nitride (CrN), titanium nitride (TiN), silicon nitride (Si3N4), aluminum oxide (Al2O3), chromium oxide (Cr2O3), titanium oxide (Ti2O3), and silicon oxide (SiO2).

The second metal layer may include at least one selected from a group consisting of aluminum (Al), chromium (Cr), titanium (Ti), and Tin (Sn).

The plastic member may further include an adhesive layer including at least one selected from a group consisting of aluminum (Al), chromium (Cr), titanium (Ti), tin (Sn), aluminum nitride (AlN), chromium nitride (CrN), titanium nitride (TiN), and tin nitride (Sn3N4), wherein the adhesive layer may be interposed between the plastic object and the first metal layer.

The plastic member may further include a protective layer including at least one selected from a group consisting of polytetrafluoroethylene (PTFE) and silicon oxide (SiO2) on the second metal layer.

According to an aspect of another exemplary embodiment, there is provided an electronic product including a housing, and a multilayer thin film coupled to a surface of the housing, wherein the multilayer thin film includes a reflective metal layer coupled to the surface of the housing, and a transparent ceramic layer coupled to the reflective metal layer.

The housing may include an accessory of the housing.

The reflective metal layer may include at least one selected from a group consisting of gold (Au), silver (Ag), aluminum (Al), chromium (Cr), titanium (Ti), and Tin (Sn).

The transparent ceramic layer may include at least one selected from a group consisting of aluminum nitride (AlN), chromium nitride (CrN), titanium nitride (TiN), silicon nitride (Si3N4), aluminum oxide (Al2O3), chromium oxide (Cr2O3), titanium oxide (Ti2O3), and silicon oxide (SiO2).

The electronic product may further include a hardness enhancement layer interposed between the surface of the housing and the reflective metal layer.

The hardness enhancement layer may include a first hardness enhancement layer including chromium (Cr) and coupled to the surface of the housing, and a second hardness enhancement layer including at least one selected from a group consisting of titanium nitride (TiN), chromium nitride (CrN), and aluminum nitride (AlN) and coupled to the first hardness enhancement layer.

According to an aspect of another exemplary embodiment, there is provided an electronic product including a housing including a plastic object, and a multilayer thin film coupled to a surface of the housing, wherein the multilayer thin film includes a first metal layer coupled to the surface of the housing, and a second metal layer coupled to the first metal layer and having a refractive index that is smaller than a refractive index of the first metal layer.

The housing may include an accessory of the housing.

The first metal layer may include at least one selected from a group consisting of aluminum nitride (AlN), chromium nitride (CrN), titanium nitride (TiN), silicon nitride (Si3N4), aluminum oxide (Al203), chromium oxide (Cr2O3), titanium oxide (Ti2O3), and silicon oxide (SiO2).

The second metal layer may include at least one selected from a group consisting of aluminum (Al), chromium (Cr), titanium (Ti), and Tin (Sn).

The multilayer thin film may further include an adhesive layer including at least one selected from a group consisting of aluminum (Al), chromium (Cr), titanium (Ti), tin (Sn), aluminum nitride (AlN), chromium nitride (CrN), titanium nitride (TiN), and tin nitride (Sn3N4), and the adhesive layer is interposed between the surface of the plastic object and the first metal layer.

The multilayer thin film may further include a protective layer including at least one selected from a group consisting of PTFE and silicon oxide (SiO2) on the second metal layer.

### BRIEF DESCRIPTION OF THE DRAWINGS

The above and/or other aspects will become apparent and more readily appreciated from the following description of exemplary embodiments, taken in conjunction with the accompanying drawings of which:

FIG. 1 is a view showing an example of a sputtering deposition device for performing a method of manufacturing a multilayer thin film in accordance with an exemplary embodiment;

FIGS. 2A, 2B, and 2C are views showing a process in which a method of manufacturing a multilayer thin film is performed using a sputtering deposition device, similar to the device shown in FIG. 1, in accordance with an exemplary embodiment;

FIG. 3 is a view showing an example of a sputtering deposition device for performing a method of manufacturing a multilayer thin film in accordance with another exemplary embodiment;

FIGS. 4A, 4B, and 4C are views showing a process in which a method of manufacturing a multilayer thin film is performed using a sputtering deposition device, similar to the device shown in FIG. 3, in accordance with an exemplary embodiment;

FIG. 5 is a view showing a structure of a plastic member including a reflective metal layer and a metal ceramic layer in accordance with an exemplary embodiment;

FIG. 6 is a view showing a propagating path of light incident to a plastic member similar to the plastic member shown in FIG. 5 in accordance with an exemplary embodiment;

FIG. 7 is a view showing a structure of a plastic member further including a hardness enhancement layer in addition to a reflective metal layer and a metal ceramic layer in accordance with an exemplary embodiment;

FIG. 8 is a view showing a structure of a plastic member further including a protective layer in addition to a reflective metal layer and a metal ceramic layer in accordance with an exemplary embodiment;

FIG. 9 is a view showing a structure of a plastic member including a first metal layer and a second metal layer in accordance with an exemplary embodiment;

FIG. 10 is a view showing a propagating path of light incident to a plastic member similar to the plastic member shown in FIG. 9 in accordance with an exemplary embodiment;

FIG. 11 is a view showing a structure of a plastic member further including an adhesive layer in addition to a first metal layer and a second metal layer in accordance with an exemplary embodiment;

FIG. 12 is a view showing a structure of a plastic member further including a protective layer in addition to an adhesive layer, a first metal layer, and a second metal layer in accordance with an exemplary embodiment;

FIG. 13 is a view showing a television (TV) with an exterior formed by a housing on which a multilayer thin film, similar to that shown in FIG. 5, is deposited on a surface as an example of an electronic product in accordance with an exemplary embodiment;

FIG. 14 is a perspective view showing a communication device including a housing on which a multilayer thin film, similar to that shown in FIG. 7, is deposited on a surface as an example of an electronic product in accordance with another exemplary embodiment;

FIG. 15 is a rear view showing a rear surface of a communication device similar to that shown in FIG. 14 in accordance with an exemplary embodiment;

FIG. 16 is a view showing a washing machine with an exterior formed by a housing on which a multilayer thin film, similar to that shown in FIG. 9, is deposited on a surface as an example of an electronic product in accordance with another exemplary embodiment; and

FIG. 17 is a view showing a refrigerator with an exterior formed by a housing on which a multilayer thin film, similar to that shown in FIG. 11, is deposited on a surface as an example of an electronic product in accordance with another exemplary embodiment.

### DETAILED DESCRIPTION

The embodiments described in this specification and configurations illustrated in drawings are only exemplary. Thus, it is understood that the inventive concept covers various equivalents, modifications, and substitutions at the time of filing of this application.

Hereinafter, exemplary embodiments will be described in detail with reference to the accompanying drawings.

A method of manufacturing a multilayer thin film in accordance with an exemplary embodiment may be performed by a multilayer thin film manufacturing device. Specifically, the method may include modifying a surface of a plastic object by a plasma treatment, depositing a reflective metal layer on the plastic object, and depositing a transparent ceramic layer on the reflective metal layer.

The plasma treatment and the deposition of the multilayer thin film may be performed by a sputtering method. It may be understood that the multilayer thin film manufacturing device in the specification includes a sputtering deposition device.

The sputtering method may be a typical physical vapor deposition method. Specifically, the sputtering method may be a method in which an inert gas is accelerated and collided with a solid target sample in a vacuum chamber and atoms are ejected from the solid target sample by energy generated during the collision, and the method may be used for forming a metal layer in the form of a thin film to manufacture a semiconductor, a display device, and the like, or depositing a metal oxide layer.

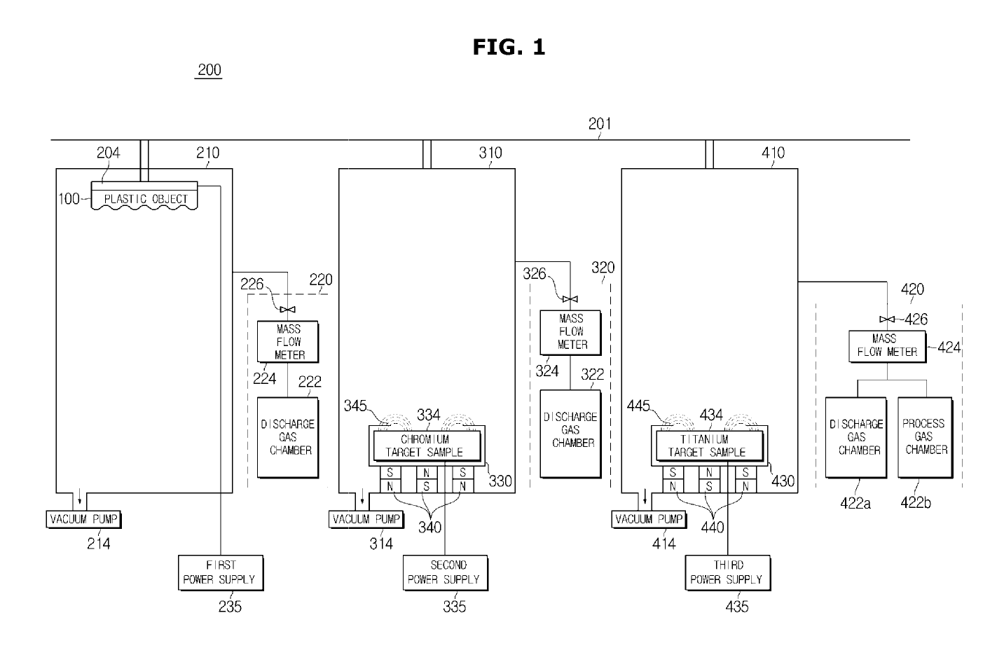

Hereinafter, a configuration of the sputtering deposition device will be described as an example of the multilayer thin film manufacturing device, and then the method of manufacturing the multilayer thin film in accordance with the exemplary embodiment will be described. FIG. 1 is a view showing an example of a sputtering deposition device 200 for performing the method of manufacturing the multilayer thin film in accordance with the exemplary embodiment.

Referring to FIG. 1, the sputtering deposition device 200 may include a plurality of vacuum chambers 210, 310, and 410, vacuum pumps 214, 314, and 414, a plurality of gas supply systems 220, 320, and 420, a rail 201, target samples 334 and 434, guns 330 and 430, and a plurality of magnetrons 340 and 440.

The vacuum pumps 214, 314, and 414 are provided on side surfaces of the vacuum chambers 210, 310, and 410, respectively, and maintain vacuum states of the vacuum chambers 210, 310, and 410, respectively.

The gas supply systems 220, 320, and 420 may be provided on side walls of the vacuum chambers 210, 310, and 410, respectively, and may supply gas into the vacuum chambers 210, 310, and 410.

The gas supply systems 220, 320, and 420 may include discharge gas chambers 222, 322, and 422a in which a discharge gas to be ionized is stored, a process gas chamber 422b in which a nitrogen (N₂) gas or an oxygen (O₂) gas provided as a process gas for a plasma chemical deposition is stored, mass flow meters 224, 324, and 424 which connect the vacuum chambers 210, 310, and 410 to the gas chambers 222, 322, 422a, and 422b, and control valves 226, 326, and 426 which control gas flowing from the gas chambers 222, 322, 422a, and 422b to the vacuum chambers 210, 310, and 410.

An argon (Ar) gas may be stored in the discharge gas chambers 222, 322, and 422a and a mixture of other inert gases in addition to the argon (Ar) gas may also be stored. Hereinafter, it will be assumed that the argon (Ar) gas is used as the discharge gas for convenience of description.

The rail 201 is provided over the vacuum chambers 210, 310, and 410, and moves an object to be deposited. Specifically, the object to be deposited is fixed to a jig 204 and moved along the rail 201.

The object to be deposited may be a planar plastic object 100 and also a part including a plastic material, in which a curved surface or a protruding part is included in a part of a surface. Further, the planar plastic object or the part including a plastic object may be transparent or non-transparent. As an example, a plastic object of a curved shape is shown in FIG. 1.

The guns 330 and 430 are provided inside the vacuum chambers 310 and 410. Because the guns 330 and 430 are connected to negative powers through second and third power supplies 335 and 435, negative electric fields are generated and discharged when the second and third power supplies 335 and 435 supply power to the guns 330 and 430. The argon (Ar) gas and the power supplied from the second and third power supplies 335 and 435 collide, generating plasma while creating an argon ion (Ar⁺).

The target samples 334 and 434 are provided inside the vacuum chambers 310 and 410 and are located opposite the object to be deposited. As described above, the object to be deposited may have a planar shape or a curved shape, and a plurality of target samples 334 and 434 may be used depending on a shape of the object to be deposited. Because a multilayer thin film having a metal component will be manufactured in one or more exemplary embodiments, a metallic material may be used as the target samples 334 and 434.

The magnetrons 340 and 440 are provided inside the vacuum chambers 310 and 410 and the plurality of magnetrons may be installed under the target samples 334 and 434.

Magnetic fields 345 and 445 are formed by the magnetrons 340 and 440, and thus electrons separated from the argon (Ar) gas move in a spiral path by simultaneously receiving forces of the magnetic fields 345 and 445 formed by the magnetrons 340 and 440 and the existing electric field. Because the electrons that move in a spiral path are trapped in the magnetic fields 345 and 445 making escaping difficult, a density of the electrons in the plasma is increased. Because of this, ionized argon (Ar) is increased in the vacuum chambers 310 and 410, the number of the argon (Ar) ions colliding with the target samples 334 and 434 is also increased, and thus efficiency of a thin film deposition is improved.

Hereinafter, a method of manufacturing the multilayer thin film will be described. The method of manufacturing the multilayer thin film using the multilayer thin film manufacturing device 200 in accordance with an exemplary embodiment includes modifying a surface of the plastic object 100 by a plasma treatment, depositing a reflective metal layer on the plastic object 100, and depositing a transparent ceramic layer on the reflective metal layer.

The depositing of the reflective metal layer on the plastic object 100 may include providing a target sample including at least one selected from a high reflectivity material group consisting of gold (Au), silver (Ag), aluminum (Al), chromium (Cr), titanium (Ti), and tin (Sn). The depositing of the transparent ceramic layer 120 on the reflective metal layer may include providing a target sample including at least one selected from a group consisting of aluminum (Al), chromium (Cr), titanium (Ti), and silicon (Si), injecting a reaction gas including nitrogen (N₂) and oxygen (O₂), applying a power source to the multilayer thin film manufacturing device 200, and reacting the target sample with the reaction gas.

Hereinafter, as an example, the method including the depositing of the reflective metal layer including chromium (Cr) on the plastic object 100 and the depositing of the transparent ceramic layer including titanium nitride (TiN) on the reflective metal layer will be described. During the depositions, temperatures of the target samples 334 and 434 may be maintained in a range of a room temperature to 200° C., and a temperature of the object to be deposited may be maintained in a range of 60° C. to 70° C.

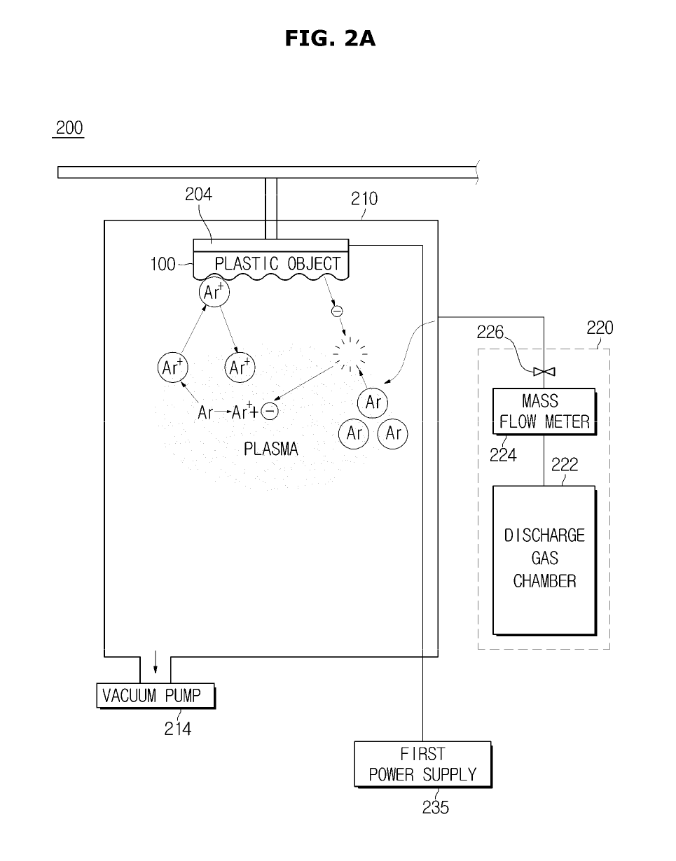

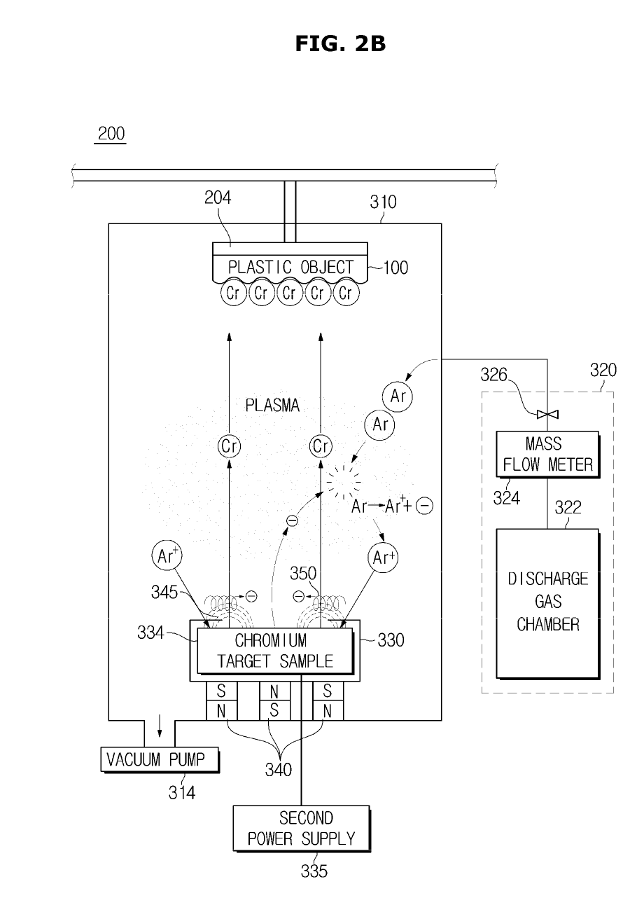

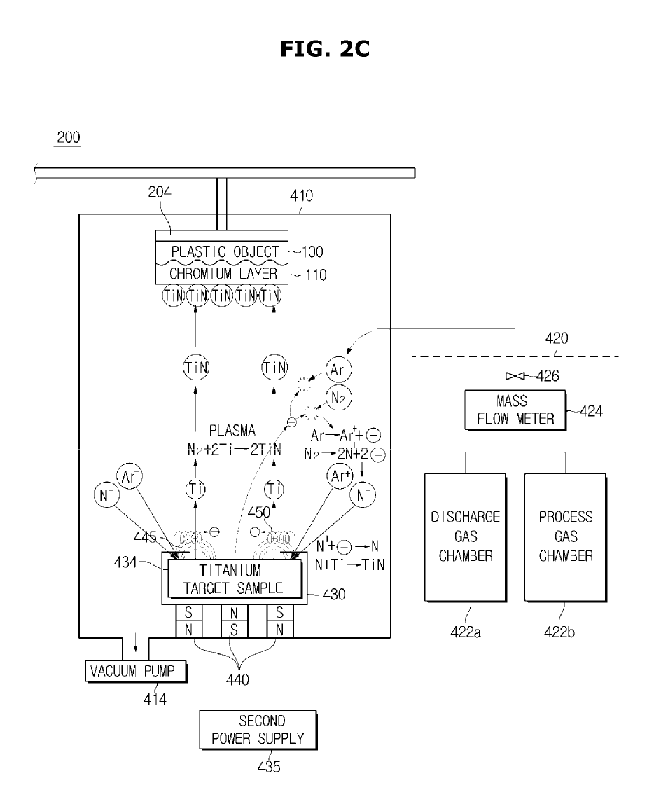

Detailed description of the method of manufacturing the multilayer thin film is as follows. FIGS. 2A, 2B, and 2C are views showing a process in which a method of manufacturing a multilayer thin film is performed using a sputtering deposition device 200 similar to that shown in FIG. 1 in accordance with an exemplary embodiment.

Referring to FIG. 2A, the method of manufacturing the multilayer thin film in accordance with the exemplary embodiment includes moving the plastic object 100 having a curved surface to the first vacuum chamber 210 of the sputtering deposition device 200, and modifying the surface of the plastic object 100 through plasma irradiation into an appropriate condition.

In this case, when power is supplied to the gun through a first power supply 235 and then a negative electric field is created, discharging starts in the first vacuum chamber 210 generating plasma.

Specifically, an argon (Ar) gas injected into the first vacuum chamber 210 is ionized as in the following Reaction Formula 1 by collisions with first and third electrons, and thus the plasma is generated.

Ar→Ar⁺+e⁻ Reaction Formula 1

The argon (Ar) gas may be used as a discharge gas and a mixture of other inert gases may also be used. Hereinafter, it will be assumed that the argon (Ar) gas is used for convenience of description.

The power supply may use a DC power source, a pulsed DC power source, or a radio frequency (RF) power source. The RF power source may be used as the first power supply 235 so that the modifying effect through plasma heating is maximized while damage of the plastic object 100 is prevented during a plasma treatment.

Specifically, the RF power source continuously changes power applied to a target using a frequency of approximately 13.56 MHz from negative to positive, or from positive to negative. While an argon ion (Ar⁺) in a plasma state is accelerated toward the plastic object 100 when the RF power source is negative, the RF power source is changed to positive and thus the argon ion (Ar⁺) is separated from the surface of the plastic object 100 when trying to attach to the surface after the sputtering. Using this principle, the plasma state may be maintained, and thus the RF power source may be used for modifying the plastic object 100 which is non-conductive.

As the surface of the plastic object 100 is modified through the plasma processing, adhesion of a film to be subsequently formed may be increased, and any foreign substance attached to the surface may be removed.

Surface modification may include contamination removal, surface activation, etching, and cross linking. Surface contamination removal includes the use of the physical and/or chemical plasma energy to remove micron-level contamination. Plasma surface activation uses gases, for example oxygen, nitrogen, hydrogen, and ammonia. When exposed to the plasma, the gases will dissociate and react with the surface, creating different functional chemical groups on the surface. Plasma etching may be based on the chemical reactivity of the discharge and includes source gases that dissociate within the plasma, creating a mixture of highly reactive species. Plasma-induced cross linking uses inert gases such as argon or helium to remove some atomic species from the surface, and generates reactive surface radicals. These radicals react within the surface forming chemical bonds, which results in a cross-linked surface. Argon plasma effectively sputters nanometers of material from the sample surface, roughening the surface on the nanometer scale. The cross linking that results may improve the adhesive properties of metal layers to the plasma-treated surface.

When the surface modification is completed, the deposition of the multilayer thin film on the plastic object 100 is performed through the sputtering method.

Specifically, in order to deposit the reflective metal layer on the plastic object 100 of which the surface is modified, the plastic object 100 which is plasma treated is mounted in an upper part of the second vacuum chamber 310 and a chromium (Cr) target sample is located on a lower part of the second vacuum chamber 310 as shown in FIG. 2B. Then, the control valve 326 is controlled while the second vacuum chamber 310 is maintained in a vacuum state by the vacuum pump 314, and then an argon (Ar) gas is injected inside the second vacuum chamber 310.

Then, when the power is supplied to the gun 330 through the second power supply 335, discharging is started, a reaction such as Reaction Formula 1 described above occurs, and thus plasma in which the argon (Ar) gas is ionized is formed. Here, a positively charged argon ion (Ar⁺) collides with the chromium (Cr) target sample, a chromium (Cr) atom is ejected, and then the reflective metal layer is formed.

The second power supply 335 may use a DC power source, a pulsed DC power source, or an RF power source. Here, because a density of the deposited layer is not high when using the DC power source and a deposition speed of the chromium (Cr) atom is slow when using the RF power source, the pulsed DC power source may be used as the second power supply 335.

The pulsed DC power source may have a voltage in a range of 0 V to 600 V and the reflective metal layer may be formed to have a thickness in a range of 1 nm to 500 nm.

When the deposition of the reflective metal layer 110 is completed, the deposition of a metal ceramic layer on the reflective metal layer 110 is performed.

Specifically, in order to deposit the metal ceramic layer including titanium nitride (TiN) on the reflective metal layer 110, the plastic object 100 on which the reflective metal layer 110 is formed is mounted in an upper part of the third vacuum chamber 410 and a titanium (Ti) target sample is mounted on a lower part of the third vacuum chamber 410 as shown in FIG. 2C.

Then, the control valve 426 is controlled while the third vacuum chamber 410 is maintained in a vacuum state by the vacuum pump 414, and then an argon (Ar) gas and a nitrogen (N₂) gas are injected inside the third vacuum chamber 410. When the power is supplied to the gun 430 through the third power supply 435, discharging is started, reactions such as Reaction Formula 1 described above and the following Reaction Formula 2 occur, and then plasma in which the argon (Ar) gas and the nitrogen (N₂) gas are simultaneously ionized is formed.

N₂→2N⁺ Reaction Formula 2

In this case, not all of the nitrogen (N₂) gas is ionized. Some amount of the nitrogen (N2) gas may be present in a molecular state and another amount of the nitrogen (N₂) gas may be in an ionized state.

Specifically, the ionized argon gas (Ar⁺) and the ionized nitrogen gas (N⁺) are attracted and accelerated toward a titanium (Ti) target sample 434 which acts as a negative power by receiving a force of the electric field. The accelerated argon ion (Ar⁺) is collided with the titanium (Ti) target sample 434, transfers energy to a surface of the target sample 434, and then a titanium atom (Ti) of the target sample 434 is ejected. Here, the titanium atom (Ti) having high energy reacts with the nitrogen (N₂) gas injected inside the third vacuum chamber 410 as shown in Reaction Formula 3, and then the transparent ceramic layer 120 of a titanium nitride (TiN) component is formed.

2Ti+N₂→2TiN Reaction Formula 3

Because the method of manufacturing the multilayer thin film in accordance with the exemplary embodiment includes the deposition of the transparent ceramic layer 120, adjusting the method so that the titanium (Ti) target sample 434 and the nitrogen (N₂) gas completely react may be implemented.

The partially ionized nitrogen gas (N⁺) attracted and accelerated toward the titanium (Ti) target sample 434 is collided with the surface of the titanium (Ti) target sample 434 as shown in Reaction Formula 4, receives electrons and is neutralized (see Reaction Formula 4 (1)), and some thereof react with titanium (Ti) (see Reaction Formula 4 (2)) and titanium nitride (TiN) is also formed.

N⁺+e⁻→N (1)

N+Ti→TiN (2) Reaction Formula 4

The third power supply 435 of the third vacuum chamber shown in FIG. 2C may use a DC power source, a pulsed DC power source, or an RF power source. Here, because a density of the deposited layer is not high when using the DC power source, a deposition speed of the titanium nitride (TiN) is slow when using the RF power source, and thus a deposition rate is reduced, i the pulsed DC power source may be used as the third power supply 435.

The pulsed DC power source may have a voltage in a range of 0 V to 600 V and the transparent ceramic layer is adjusted to have a thickness in a range of 1 nm to 500 nm so that various colors in addition to a unique color included in a metal are implemented. A principle of color implementation of the transparent ceramic layer will be described in detail in the following related section.

Further, because the pulsed DC power source has a better deposition rate compared to the RF power source, but a worse deposition rate compared to the DC power source, at least one chamber in the same condition as the second vacuum chamber 310 may further be provided next to the third vacuum chamber 410 and then deposition of titanium nitride (TiN) may be performed.

Hereinafter, a method of manufacturing a multilayer thin film in accordance with another exemplary embodiment will be described in detail.

The method of manufacturing the multilayer thin film in accordance with another exemplary embodiment may further include depositing at least one hardness enhancement layer on the plastic object 100 so as to enhance the hardness of the plastic object 100 after modifying the surface of the plastic object 100 by the plasma treatment.

Here, the depositing of at least one hardness enhancement layer on the plastic object 100 may include depositing a first hardness enhancement layer including chromium (Cr) on the plastic object 100 and depositing a second hardness enhancement layer including at least one selected from a group consisting of titanium nitride (TiN), chromium nitride (CrN), and aluminum nitride (AlN) on the first hardness enhancement layer. Hereinafter, as an example, the depositing of the single hardness enhancement layer including titanium nitride (TiN) will be described for convenience of description.

In order to additionally perform the depositing of the hardness enhancement layer, a fourth vacuum chamber may be additionally provided before the first vacuum chamber of the sputtering deposition device 200. Here, reaction generated in the fourth vacuum chamber in order to deposit the hardness enhancement layer is similar to the reactions generated in the third vacuum chamber. Repeated descriptions of the reactive sputtering deposition method in the third vacuum chamber described above will be omitted for convenience of description.

In the fourth vacuum chamber, the hardness enhancement layer including titanium nitride (TiN) may be formed in the same manner as the above-described process. Because the hardness enhancement layer is only a layer provided so as to increase the hardness of the plastic object 100 and enhance scratch resistance, it is unnecessary that titanium (Ti) and a nitrogen (N₂) gas completely react, and in general, it may be adjusted so that the nitrogen (N₂) gas in a range of about 30% to about 70% reacts.

Further, the hardness of the plastic object 100 is enhanced according to increasing an injection degree of titanium (Ti) which is a target sample and the scratch resistance performance may be improved.

The pulsed DC power source may be used as the fourth power supply in the same manner as the third power supply, the power source and time may be adjusted so that the hardness enhancement layer with respect to adjustment of the power source may be formed to have a thickness in a range of 1 nm to 500 nm in order to achieve efficient hardness enhancement.

Next, a method of manufacturing a multilayer thin film in accordance with still another exemplary embodiment will be described.

The method of manufacturing the multilayer thin film in accordance with still another exemplary embodiment may be performed using a multilayer thin film manufacturing device, and may include modifying a surface of a plastic object by a plasma treatment, depositing a first metal layer on the plastic object, and depositing a second metal layer having a refractive index smaller than the first metal layer on the first metal layer.

The plasma treatment and the multilayer thin film deposition may be performed by applying the sputtering method as described above. The method of manufacturing the multilayer thin film is performed using a multilayer thin film manufacturing device different from a configuration of FIG. 1. Hereinafter, a configuration of the sputtering deposition device to which the exemplary embodiment is applied will be described and then the method of manufacturing the multilayer thin film in accordance with the exemplary embodiment will be described.

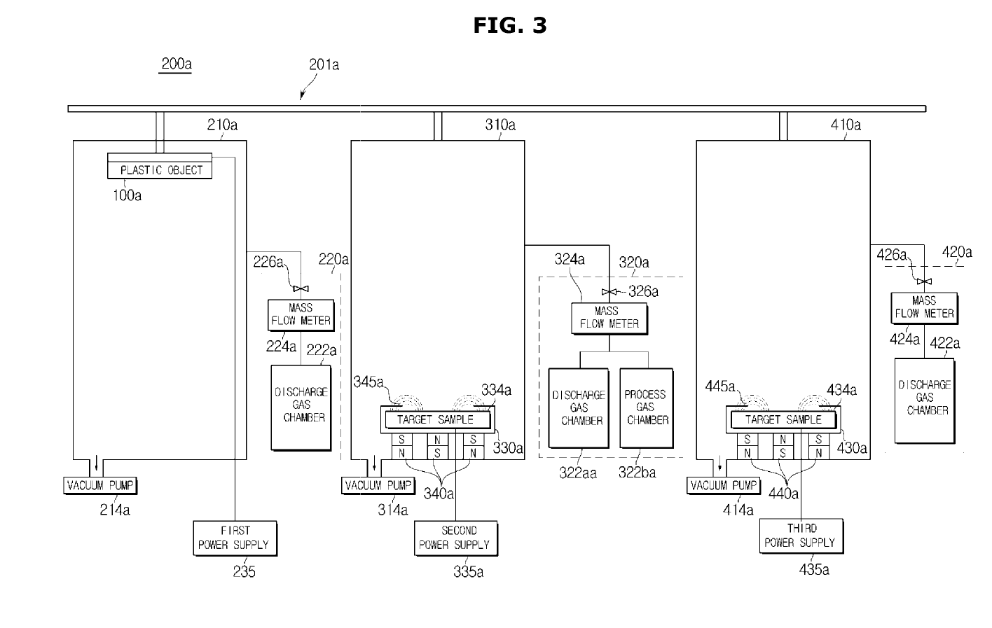

FIG. 3 is a view showing an example of a sputtering deposition device 200a for performing a method of manufacturing a multilayer thin film in accordance with another exemplary embodiment.

Referring to FIG. 3, the sputtering deposition device 200a may include a plurality of vacuum chambers 210a, 310a, and 410a, vacuum pumps 214a, 314a, and 414a, gas supply systems 220a, 320a, and 420a, a rail 201a, target samples 334a and 434a, guns 330a and 430a, and a plurality of magnetrons 340a and 440a. The vacuum chambers 210a, 310a, and 410a, the vacuum pumps 214a, 314a, and 414a, the guns 330a and 430a, the plurality of magnetrons 340a and 440a are substantially the same as the configuration of FIG. 1 and repeated description thereof will be omitted.

The gas supply systems 220a, 320a, and 420a may be provided on side walls of the vacuum chambers 210a, 310a, and 410a, respectively, and may supply gas into the vacuum chambers 210a, 310a, and 410a, respectively.

The gas supply systems 220a, 320a, 420a may include discharge gas chambers 222a, 322aa, and 422a in which an argon (Ar) gas to be ionized is stored, a process gas chamber 322ba in which a nitrogen (N₂) gas or an oxygen (O₂) gas provided as a process gas for a plasma chemical deposition process are stored, mass flow meters 224a, 324a, and 424a which connect the vacuum chambers 210a, 310a, and 410a to the gas chambers 222a, 322aa, 322ba, and 422a, and control valves 226a, 326a, and 426a which control the gas flowing from the gas chambers 222a, 322aa, 322ba, and 422a to the vacuum chambers 210aa, 310aa, and 410aa.

The rail 201a is provided over the vacuum chambers 210a, 310a, and 410a, and moves a target to be deposited. The object to be deposited may be a planar plastic object and also a part including a plastic material, in which a curved surface or a protruding part is included in a part of a surface. Further, the planar plastic object or the part including the plastic material may be transparent or non-transparent. An example of a transparent plastic object 100a of a planar shape is shown in FIG. 3.

The target sample 334a and 434a are provided inside the vacuum chambers 310a and 410a and located opposite to the object to be deposited. As described above, the object to be deposited may have a planar shape or a curved shape, and a plurality of target samples 334a and 434a may be used depending on a shape of the object to be deposited. Because the multilayer thin film having a metal component will be manufactured in one or more exemplary embodiments, a metallic material may be used for the target samples 334a and 434a.

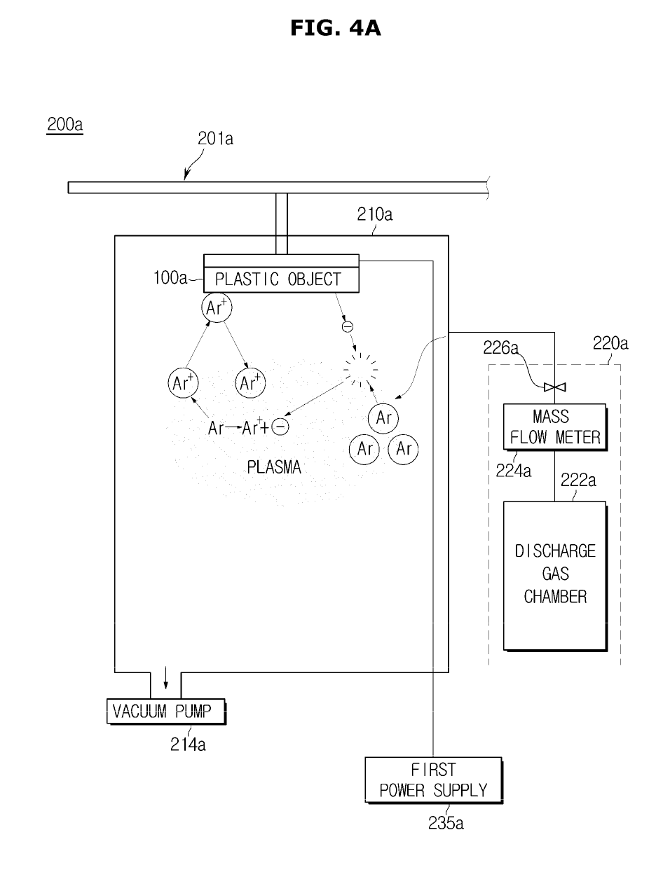

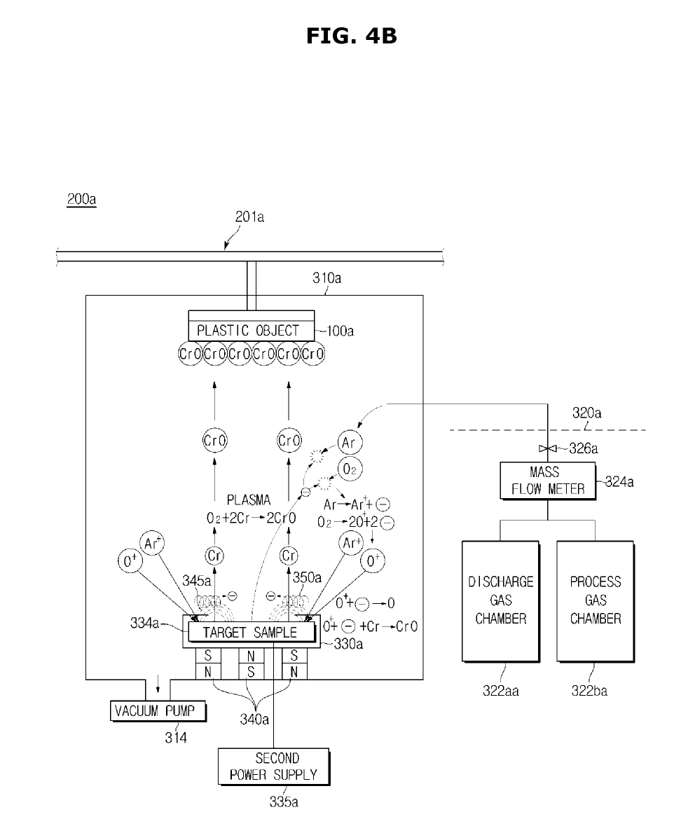

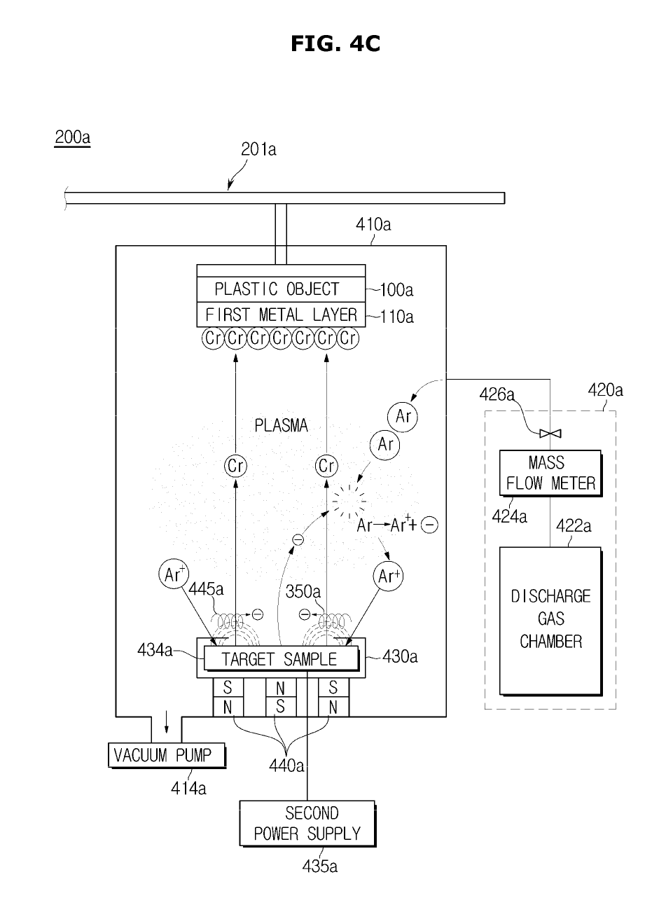

FIGS. 4A to 4C are views showing a process in which a method of manufacturing a multilayer thin film is performed using the sputtering deposition device 200a shown in FIG. 3 in accordance with an exemplary embodiment.

The method of manufacturing the multilayer thin film in accordance with the exemplary embodiment includes modifying a surface of the plastic object 100a, depositing the first metal layer 110a on the plastic object 100a, and depositing the second metal layer 120a having a refractive index smaller than the first metal layer 110a on the first metal layer 110a.

The depositing of the first metal layer 110a on the plastic object 100a may include providing a metallic material including at least one component selected from a group consisting of aluminum (Al), chromium (Cr), titanium (Ti), and Tin (Sn), injecting at least one reaction gas selected from a group consisting of nitrogen (N₂) and oxygen (O₂), applying power source to the sputtering deposition device 200a, and reacting the metallic material with the reaction gas.

Further, the depositing of the second metal layer 120a having a refractive index smaller than the first metal layer 110a on the first metal layer 110a may include providing a metallic material including at least one selected from a group consisting of aluminum (Al), chromium (Cr), titanium (Ti), and Tin (Sn), and applying the power source to the sputtering deposition device 200a.

An example of the process of manufacturing the multilayer thin film which includes the first metal layer 110a including chromium oxide (CrO) and the second metal layer 120a including chromium (Cr) on the transparent plastic object 100a, and the method of manufacturing the multilayer thin film will be described in detail.

First, as shown in FIG. 4A, the method includes moving the processed transparent plastic object 100a to the first vacuum chamber 210a of the sputtering deposition device 200a, and modifying the surface of the plastic object 100a through plasma irradiation into an appropriate condition.

In this case, when power is supplied to the gun through a first power supply 235a and then a negative electric field is created, discharging starts in the first vacuum chamber 210a generating plasma. Description for a generation process of the plasma, discharge gas, and the power supply are the same as FIG. 2A, and the following repeated descriptions will be omitted.

When the modification of the surface is completed, the multilayer thin film is deposited on the plastic object 100a through the sputtering method.

The method of manufacturing the multilayer thin film in accordance with the exemplary embodiment includes depositing the first metal layer 110a and the second metal layer 120a having a refractive index smaller than the first metal layer 110a so that a deep translucent metal sense is implemented and a different color is implemented depending on a viewing angle on the transparent plastic object 100a or a product. In this case, the metal sense may be adjusted by adjusting thicknesses of the first metal layer 110a and the second metal layer 120a.

Hereinafter, the depositing of the first metal layer 110a including chromium oxide (CrO) on the transparent plastic object 100a will be described in detail.

Before depositing the chromium oxide (CrO), the plastic object 100a, which is plasma treated, is mounted in an upper part of the second vacuum chamber 310a and chromium (Cr) is provided as the target sample 334a on a lower part of the second vacuum chamber 310a as shown in FIG. 4B.

Next, the control valve 326a is controlled and then an argon (Ar) gas and an oxygen (O₂) gas are injected into the second vacuum chamber 310a while the second vacuum chamber 310a is maintained in a vacuum state by the vacuum pump 314a.

Then, the power is supplied to the gun 330a through the second power supply 335a, discharging is started, reactions such as the above-described Reaction Formula 1 and the following Reaction Formula 5 occur, and then plasma in which the argon (Ar) gas and the oxygen (O₂) gas are simultaneously ionized is formed.

O₂→2O⁺ Reaction Formula 5

Not all of the oxygen (O₂) gas is ionized. Some amount of the oxygen (O2) gas may be present in a molecular state and another amount of the oxygen (O₂) gas may be in an ionized state.

The ionized argon ion (Ar⁺) and the ionized oxygen ion (O⁺) are attracted and accelerated toward a chromium (Cr) target sample 334a which acts as a negative power by receiving a force of an electric field. The accelerated argon ion (Ar⁺) is collided with the chromium (Cr) target sample 334a, transfers energy to a surface of the target sample 334a, and then a chromium atom (Cr) is ejected from the target sample 334a due to the energy.

The chromium atom (Cr) having high energy reacts with the oxygen (O₂) gas injected inside the second vacuum chamber 310a as shown in the following Reaction Formula 6, and thus the first metal layer 110a of a chromium oxide (CrO) component is formed.

2Cr+O₂→2CrO Reaction Formula 6

Because transparency is increased when chromium (Cr) and oxygen (O₂) completely react, it may be that an amount of oxygen (O₂) is appropriately adjusted, a reaction degree of the chromium and the oxygen is adjusted, and thus the transparency is adjusted in order to implement a metal according to a principle to be described. Further, it may be that the oxygen (O₂), which is supplied so that a deep translucent metal sense is implemented on the surface of the plastic object 100a, reacts in a range of about 30% to about 70%.

Some amount of the oxygen ion (O⁺) attracted and accelerated toward the chromium (Cr) target sample 334a receive electrons and are neutralized (see Reaction Formula 7 (1)) while colliding with the surface of the chromium (Cr) target sample 334a as shown in Reaction Formula 7. Another amount of the oxygen ion (O⁺) reacts with chromium (Cr) (see Reaction Formula 7 (2)) and then chromium oxide (CrO) is also formed.

O⁺+e⁻→O (1)

O⁺+e⁻+Cr→CrO (2) Reaction Formula 7

The second power supply 335a may use a DC power source, a pulsed DC power source, or an RF power source. Here, because a density of the deposited layer is not high when using the DC power source, a deposition speed of the chromium oxide (CrO) is slow when using the RF power source, and thus a deposition rate is reduced, the pulsed DC power source may be used as the second power supply 335a. Further, it may be that power and deposition time of the pulsed DC power source may be adjusted so that the first metal layer 110a is formed to have a thickness in a range of 1 nm to 500 nm.

Next, the deposition of the second metal layer 120a including chromium (Cr) on the first metal layer 110a will be described in detail.

When the first metal layer 110a is formed, the plastic object 100a is moved along the rail 201a and mounted in the third vacuum chamber 410a as shown in FIG. 4C in order to deposit the second metal layer 120a on the first metal layer 110a. When the plastic object 100a on which the first metal layer 110a is deposited is mounted in the third vacuum chamber 410a, the vacuum pump 414a is controlled so that the third vacuum chamber 410a is maintained in a vacuum state and a control valve 426a is controlled so that argon (Ar) gas is injected into the third vacuum chamber 410a.

Then, plasma is generated in the same manner as the first vacuum chamber 210a, a positively charged argon ion (Ar⁺) is collided with the chromium (Cr) target sample 434a, a chromium (Cr) atom is ejected, and then the second metal layer 120a including a chromium (Cr) component is deposited on the first metal layer 110a.

The third power supply 435a may use a DC power source, a pulsed DC power source, or an RF power source. Here, because a density of the deposited layer is not high when using the DC power source and a deposition speed of the chromium (Cr) atom is slow when using the RF power source, the pulsed DC power source may be used as the third power supply 435a. Further, power and deposition time of the pulsed DC power source may be adjusted so that the second metal layer 120a is formed to have a thickness in a range of 1 nm to 500 nm.

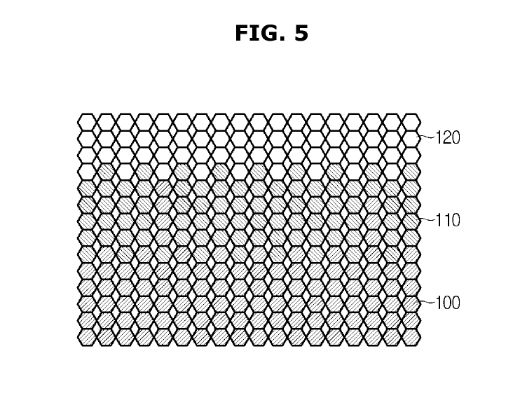

Next, a plastic member in which a multilayer thin film is formed on a surface of a plastic object will be described. First, the plastic member manufactured through the multilayer thin film manufacturing device 200 shown in FIG. 1 will be described with reference to FIGS. 5 to 8.

FIG. 5 is a view showing a structure of a plastic member in accordance to an exemplary embodiment. As shown in FIG. 5, the plastic member includes a reflective metal layer 110 deposited on a plastic object 100 and a transparent ceramic layer 120 deposited on the reflective metal layer 110.

The plastic object 100 may be smoother without a foreign substance due to a plasma treatment and provided in a planar shape or in a curved shape.

The reflective metal layer 110 may include at least one selected from a group consisting of gold (Au), silver (Ag), aluminum (Al), chromium (Cr), titanium (Ti), and Tin (Sn). The reflective metal layer 110 is a layer which is provided to implement a metal on the plastic object 100, and thus the reflective metal layer 110 may include a highly reflective material considered to be easy to facilitate by those of skilled in art in addition to the above-described elements.

The transparent ceramic layer 120 may include at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂). The transparent ceramic layer 120 is a layer which is provided so that various colors in addition to a unique color included in a metal are implemented, and thus various color tones may be realized by controlling a wavelength range of a layer thickness and by controlling the expression of the interference fringe caused by the reflection of light.

Hereinafter, a principle in which the metal sense of various colors is implemented by adjusting a thickness of the transparent ceramic layer 120 will be described in detail.

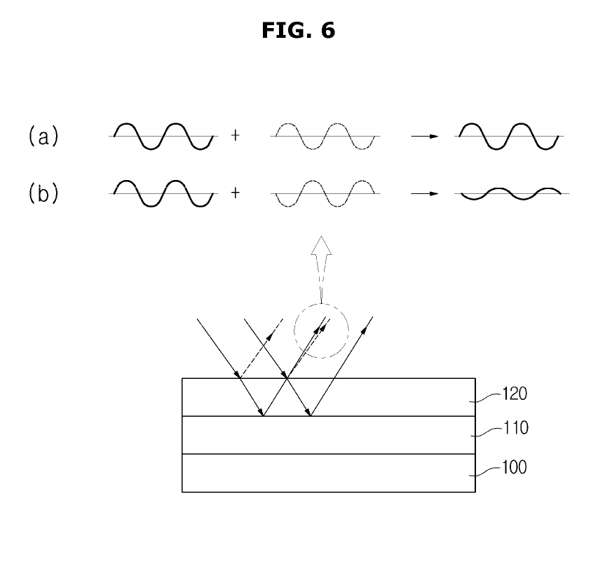

FIG. 6 is a view showing a propagating path of light incident to the plastic member having the structure shown in FIG. 5.

Referring to FIG. 6, when the light is incident to the transparent ceramic layer 120 of the plastic member in accordance to the exemplary embodiment, some amount of the light reflects off a surface of the transparent ceramic layer 120 and another amount of the light is transmitted through the transparent ceramic layer 120.

In this case, an amount of the light which reflects off the surface of the transparent ceramic layer 120, or is transmitted through the transparent ceramic layer 120, may be changed according to the transparency of the transparent ceramic layer 120. That is, the amount of the light transmitting through the transparent ceramic layer 120 is greater than that of reflecting off the surface of the transparent ceramic layer 120 as the transparency is increased, and the amount of the light transmitting through the transparent ceramic layer 120 is reduced as the transparency is decreased.

The transparent ceramic layer 120, which is provided to implement a metal, is a layer which is provided to adjust the metallic content of a reflective metal layer provided under the transparent ceramic layer 120. Thus, the transparent ceramic layer 120 may have high transparency.

Next, when the light transmitted through the transparent ceramic layer 120 reaches the reflective metal layer 110 located under the transparent ceramic layer 120, the light reflects off the reflective metal layer 110, is transmitted through the transparent ceramic layer 120, and then enters the air. Various tone expressions may be realized due to interference between a wavelength of the light which immediately reflects off the transparent ceramic layer 120 and a wavelength of the light which reflects off the reflective metal layer 110.

Specifically, the wavelength of the light which immediately reflects off the transparent ceramic layer 120 and the wavelength of the light which reflects off the reflective metal layer may be constructively interfered as shown in (a) of FIG. 6, in this case, a color of the wavelength of the constructive interference may stand out. Further, the wavelength of the light which immediately reflects off the transparent ceramic layer 120 and the wavelength of the light which reflects off the reflective metal layer may be destructively interfered as shown in (b) (b) of FIG. 6, in this case, a color of the wavelength of the destructive interference may stand out.

In this case, whether the constructive interference occurs or the destructive interference occurs is determined by a thickness and a refractive index of the transparent ceramic layer 120 coupled to the reflective metal layer.

For example, when the transparent ceramic layer 120 includes silicon oxide (SiO₂) having a refractive index of 1.4 and the thickness of 200 nm is provided, light of a purple wavelength region may be implemented outside the transparent ceramic layer 120, and when the transparent ceramic layer 120 is provided to have the thickness of 350 nm, light of a red wavelength region may be implemented outside the transparent ceramic layer 120.

In the case that the transparent ceramic layer 120 includes a material having a refractive index greater than silicon oxide (SiO₂), a color similar to the case of a refractive index of 1.4 and the thickness of 200 nm, or in the case of a refractive index of 1.4 and the thickness of 350 nm may be implemented when the silicon oxide (SiO₂) is implemented to have a thickness smaller than 200 nm or 350 nm. On the contrary, in the case that the transparent ceramic layer 120 includes a material having a refractive index greater than silicon oxide (SiO₂), a color similar to the case of a refractive index of 1.4 and the thickness of 200 nm, or in the case of a refractive index of 1.4 and the thickness of 350 nm may be implemented when the silicon oxide (SiO₂) is implemented to have a thickness greater than 200 nm or 350 nm.

In summary, as the wavelength of the interfered light is adjusted by adjusting the thickness of the transparent ceramic layer 120, various colors may be implemented. The adjustable thickness of the transparent ceramic layer 120 may be adjusted in a range of 1 nm to 500 nm in order to adjust the wavelength of the light.

Next, a structure of a plastic member in accordance to another exemplary embodiment will be described.

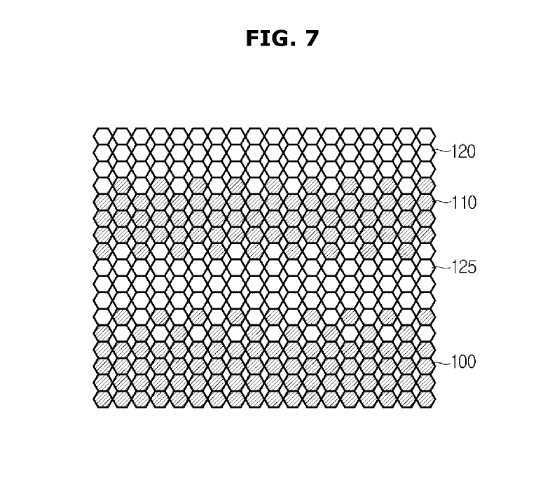

FIG. 7 is a view showing the structure of the plastic member further including a hardness enhancement layer 125 in addition to the structure shown in FIG. 5. Because a reflective metal layer 110 and a transparent ceramic layer 120 are substantially the same as FIG. 5, hereinafter, repeated descriptions as shown in FIG. 5 will be omitted.

Referring to FIG. 7, the plastic member in accordance to another exemplary embodiment may further include at least one hardness enhancement layer 125 between a plastic object 100 and the reflective metal layer 110.

The hardness enhancement layer 125 may include a first hardness enhancement layer including chromium (Cr) deposited on the plastic object 100, and a second hardness enhancement layer including at least one selected from a group consisting of titanium nitride (TiN), chromium nitride (CrN), and aluminum nitride (AlN).

Hereinafter, a structure, in which the hardness enhancement layer 125 including titanium nitride (TiN) is coupled to the plastic object 100, the reflective metal layer 110 including chromium (Cr) is coupled to the hardness enhancement layer 125, and the transparent ceramic layer 120 including titanium nitride (TiN) is deposited on the reflective metal layer 110, will be described as an example for convenience of description. It is only an example, and the plastic member in accordance to another exemplary embodiment is not limited thereto.

The titanium nitride (TiN) of the hardness enhancement layer 125 is deposited by a sputtering method. Because the titanium nitride (TiN) of the hardness enhancement layer 125 has a relatively high momentum due to a collision with a substrate in the sputtering method compared to the other physical vapor deposition (PVC) methods, a strong bonding strength with a base material is shown.

Referring to FIG. 7, it may be seen that the titanium nitride (TiN) molecules included in the hardness enhancement layer 125 have deeply penetrated into the inside of the plastic object 100. It is a structure formed by the titanium nitride (TiN) molecules colliding and penetrating into the plastic object 100 with high energy in the sputtering deposition.

Because of this, as the hardness enhancement layer 125 and the plastic object 100 are coupled and deposited with a strong bonding energy, scratch resistance of the plastic may be improved as a hardness of the plastic object 100 is increased.

Further, the titanium nitride (TiN) molecules may effectively penetrate into the inside of the plastic object 100 by adjusting parameters such as current density in the plasma, a temperature, and the like. This principle may be equally applied to the reflective metal layer 110 and the transparent ceramic layer 120.

The hardness enhancement layer 125 may be formed to have a thickness in a range of 1 nm to 500 nm. Each hardness enhancement layer 125 may be formed to have a thickness in a range of 1 nm to 500 nm when a plurality of hardness enhancement layers 125 are provided.

Next, a structure of a plastic member in accordance to still another exemplary embodiment will be described.

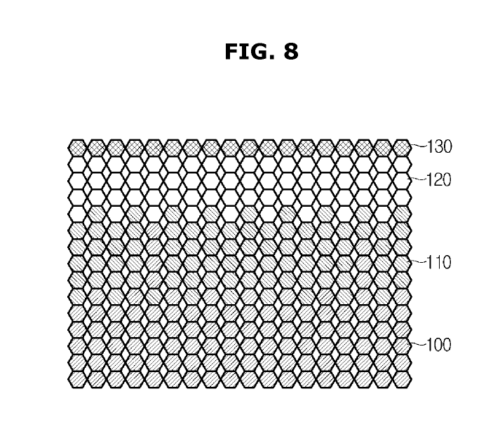

FIG. 8 is a view showing a structure of a plastic member further including a protective layer 130 in addition to the structure shown in FIG. 5. Because a reflective metal layer 110 and a transparent ceramic layer 120 are substantially the same as FIG. 5, hereinafter, repeated descriptions as shown in FIG. 5 will be omitted.

Referring to FIG. 8, the plastic member in accordance to still another exemplary embodiment may further include the protective layer 130 including at least one selected from a group consisting of polytetrafluoroethylene (PTFE) and silicon oxide (SiO₂) on the transparent ceramic layer 120.

As the protective layer 130 is a layer provided to protect a transparent metal layer from external scratching, etc., adjusting a thickness to be thinner so that interference of light is not affected may be provided.

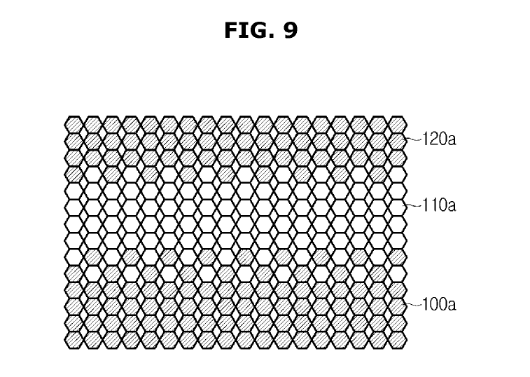

As described above, the plastic member manufactured through the sputtering deposition device 200 shown in FIG. 1 was described. Next, the plastic member manufactured through the sputtering deposition device 200a shown in FIG. 3 will be described with reference to FIGS. 9 to 12.

FIG. 9 is a view showing a structure of a plastic member in accordance with an exemplary embodiment. As shown in FIG. 9, the plastic member includes a first metal layer 110a deposited on a plastic object 100a and a second metal layer 120a deposited on the first metal layer 110a and having a refractive index smaller than the first metal layer 110a.

The plastic object 100a may be smoother without a foreign substance due to a plasma treatment, and provided in a planar shape or in a curved shape.

The first metal layer 110a may include at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂). Further, the second metal layer 120a may include at least one selected from a group consisting of aluminum (Al), chromium (Cr), titanium (Ti), and Tin (Sn). Elements included in the first metal layer 110a and the second metal layer 120a are not limited by the above-described examples, and it may be understood that modifications considered easy to be facilitated by those of skilled in art are possible within the scope.

The multilayer thin film configured as described above is implemented to have a deep translucent metal sense, and a different color may be implemented depending on a viewing angle. In addition, a metal layer may be deposited even when a surface of the plastic object 100a is not smooth.

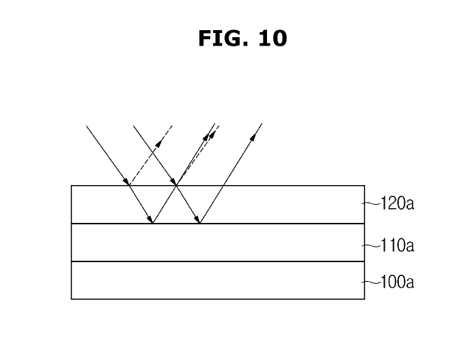

Hereinafter, a principle, in which metal senses of various colors are implemented, will be described in detail. FIG. 10 is a view showing an example of a propagating path of light incident to the plastic member.

As shown in FIG. 10, when the light is incident to the second metal layer 120a of the multilayer thin film, some amount of the incident light reflects off a surface of the second metal layer 120a, and another amount of the light is transmitted through the second metal layer 120a. When the light transmitted through the second metal layer 120a reaches the first metal layer 110a having a refractive index greater than the second metal layer 120a, the light reflects off the first metal layer 110a, is transmitted through the second metal layer 120a, and then enters the air. A deep translucent metal sense may be implemented due to interference between a wavelength of the light which immediately reflects off the second metal layer 120a and a wavelength of the light which reflects off the first metal layer 110a.

When the wavelength of the light which immediately reflects off the second metal layer 120a and the wavelength of the light which reflects off the first metal layer 110a are constructively interfered, a color of the wavelength of the constructive interference may stand out, and when the wavelengths are destructively interfered, a color of the wavelength of the destructive interference may stand out.

As described above, as the wavelength of the interfered light is adjusted by adjusting the thicknesses of the first metal layer 110a and the second metal layer 120a, various colors may be implemented. The adjustable thicknesses of the first metal layer 110a and the second metal layer 120a may be adjusted in a range of 1 nm to 500 nm in order to adjust the wavelength of the light.

Next, a structure of a plastic member in accordance to another exemplary embodiment will be described.

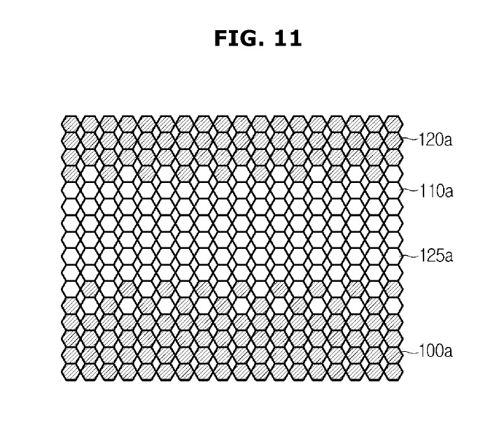

FIG. 11 is a view showing a structure of a plastic member further including an adhesive layer 125a in addition to the structure shown in FIG. 9. Because a first metal layer 110a and a second metal layer 120a are substantially the same as FIG. 9, and hereinafter repeated descriptions as shown in FIG. 9 will be omitted.

Referring to FIG. 11, the plastic member in accordance to another exemplary embodiment may further include the adhesive layer 125a between the plastic object 100a and the first metal layer 110a.

As the adhesive layer 125a is a layer provided so that the first metal layer 110a easier contacts the plastic object 100a, the adhesive layer 125a may include at least one selected from a group consisting of aluminum (Al), chromium (Cr), titanium (Ti), Tin (Sn), aluminum nitride (AlN), chromium nitride (CrN), titanium nitride (TiN), and tin nitride (Sn₃N₄).

Next, a structure of a plastic member in accordance to still another exemplary embodiment will be described.

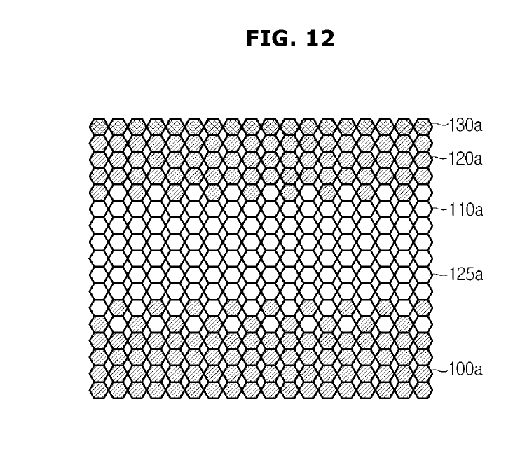

FIG. 12 is a view showing a structure of a plastic member further including a protective layer 130a in addition to the structure shown in FIG. 11. Because a first metal layer 110a, a second metal layer 120a, and an adhesive layer 125a are substantially the same as FIG. 11, hereinafter, repeated descriptions as shown in FIG. 11 will be omitted.

Referring to FIG. 11, the plastic member in accordance to still another exemplary embodiment may further include the protective layer 130a including at least one selected from a group consisting of PTFE and silicon oxide (SiO₂) on the second metal layer 120a.

As the protective layer 130a is a layer provided to protect the multilayer thin film from external scratching, etc., adjusting a thickness to be thinner so that interference of the light is not affected may be provided. The protective layer 130a may be formed to have a thickness in a range of 1 nm to 500 nm.

Next, an electronic product to which the method of manufacturing the multilayer thin film and the plastic members described above are applied will be described.

The electronic product includes a housing and a multilayer thin film coupled to all or a part of a surface of the housing. The multilayer thin film may implement a deep metal sense on a surface of a plastic housing, and the same structure as the above-described structures may be applied to the multilayer thin film.

For example, the multilayer thin film in accordance with an exemplary embodiment may include a reflective metal layer 110 coupled to all or a part of the surface of the housing and a transparent ceramic layer 120 coupled to the reflective metal layer 110. Alternatively, the multilayer thin film may include the first metal layer 110a coupled to all or a part of the surface of the housing and the second metal layer 120a coupled to the first metal layer 110a and having a refractive index smaller than the first metal layer 110a. Repeated description related to the structure of the multilayer thin film and components thereof as shown in FIGS. 5 to 12 will be omitted.

As the housing is a part, such as a case which houses a part, a frame containing an apparatus, or the like, surrounding all mechanical devices in a box shape, the housing may include accessories. Further, an accessory of the housing may be defined as a concept including a part of the housing which forms an exterior, such as a bezel unit of a TV, a stand of the TV, a bezel unit of a communication device, or a concept including a part of an electronic product.

Hereinafter, an electronic product in accordance with an exemplary embodiment will be described in detail with reference to the accompanying drawings.

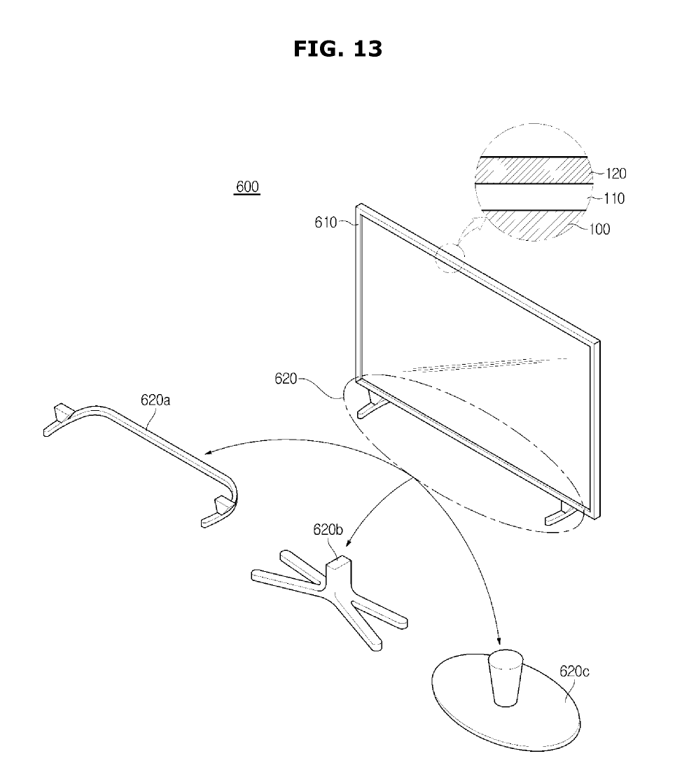

FIG. 13 is a view showing a TV 600, of which an exterior is formed by a housing in which the multilayer thin film shown in FIG. 5 is deposited on a surface, as an example of the electronic product in accordance with the exemplary embodiment.

The multilayer thin film may include a reflective metal layer 110 and a transparent ceramic layer 120.

The TV 600 may include a bezel unit 610 and stand units 620a, 620b, and 620c in which the multilayer thin film is formed. The multilayer thin film formed on the bezel unit 610 and the stand units 620a, 620b, and 620c may implement a deep metal sense on the exterior of the TV 600.

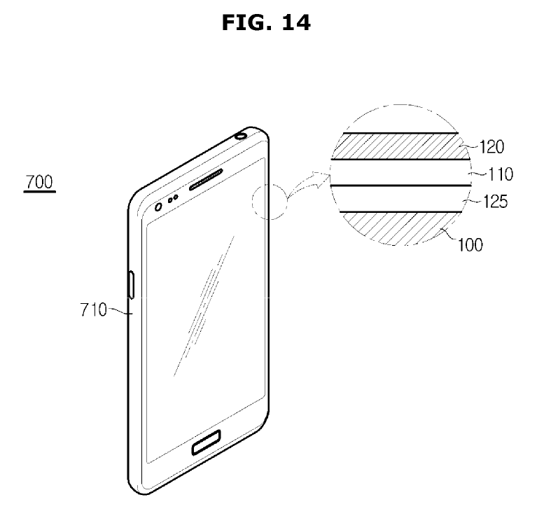

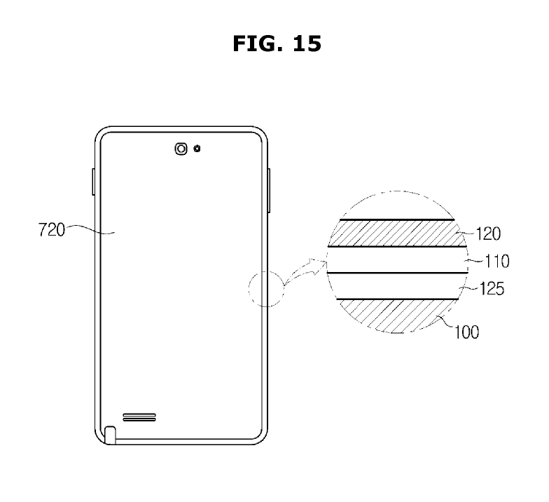

FIG. 14 is a perspective view showing a communication device 700 including a housing in which the multilayer thin film shown in FIG. 7 is deposited on a surface as an example of an electronic product in accordance with another exemplary embodiment, and FIG. 15 is a rear view showing a rear surface thereof.

The multilayer thin film may include a hardness enhancement layer 125, a reflective metal layer 110, and a transparent ceramic layer 120.

The communication device 700 may be formed by the housing. It may be understood that the housing including a bezel unit 710 of the communication device 700 and a case unit 720 of the communication device 700 is a broad concept, and the multilayer thin film formed on the housing may implement a deep metal sense on the exterior of the communication device 700.

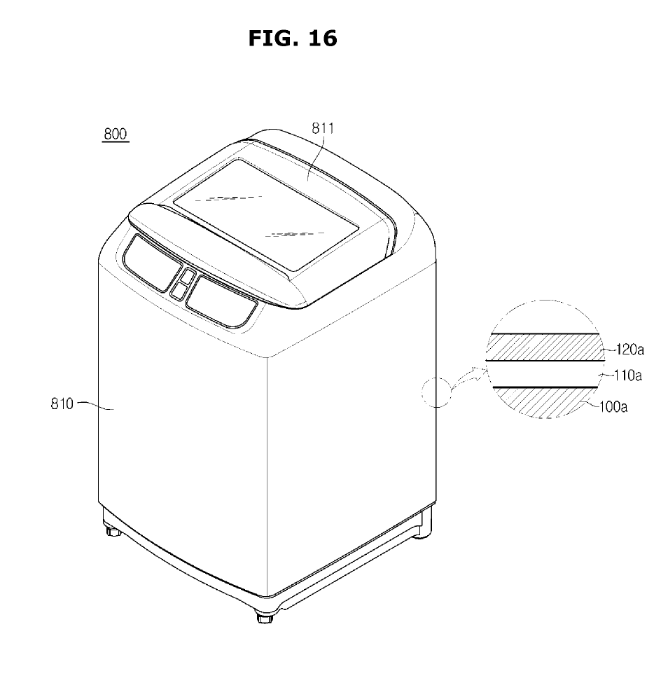

FIG. 16 is a view showing a washing machine 800, of which an exterior is formed by a housing in which the multilayer thin film shown in FIG. 9 is deposited on a surface, as an example of an electronic product in accordance with still another exemplary embodiment.

The multilayer thin film may include a first metal layer 110a and a second metal layer 120a having a refractive index smaller than the first metal layer 110a.

The exterior of the washing machine 800 may be formed by the housing 810, and the washing machine 800 may be opened by a lid 811 provided on an upper part thereof. It may be understood that the housing 810 including the lid 811 is a broad concept, and the multilayer thin film formed on the housing 810 may implement a deep metal sense on the exterior of the washing machine 800.

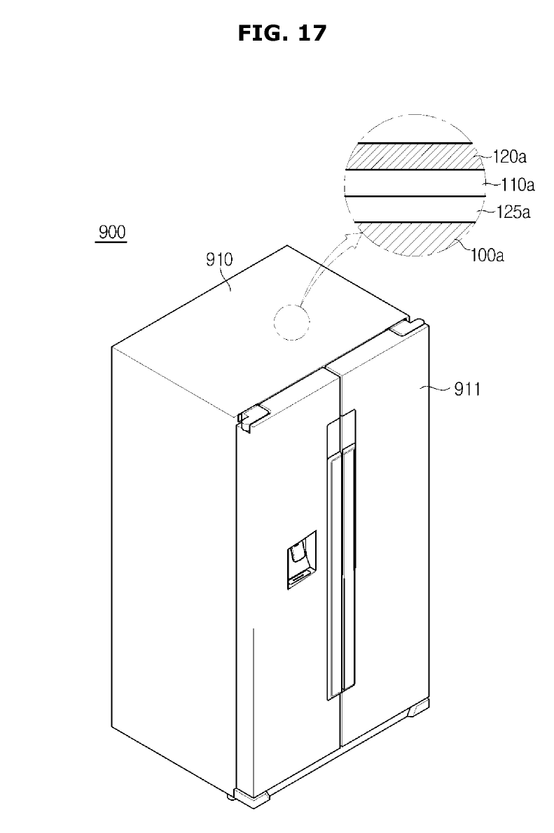

FIG. 17 is a view showing a refrigerator 900, of which an exterior is formed by a housing in which the multilayer thin film shown in FIG. 11 is deposited on a surface, as an example of an electronic product in accordance with yet another exemplary embodiment.

The multilayer thin film may include an adhesive layer 125a, a first metal layer 110a, and a second metal layer 120a having a refractive index smaller than the first metal layer 110a.

The exterior of the refrigerator 900 may be formed by a housing 910, and the refrigerator 900 may be opened by a door 911 provided on a front surface thereof. It may be understood that the housing 910 including the door 911 is a broad concept, and the multilayer thin film included in the housing 910 may implement a deep metal sense on the exterior of the refrigerator 900.

From the above-described, the exemplary embodiments of the method of manufacturing the multilayer thin film, the plastic member in which the multilayer thin film is formed, and the electronic product including the same were described. The technical concept of is not limited by the exemplary embodiments described above, and it should be understood that modifications considered easy to be facilitated by those of skilled in art are possible within the scope.

The following effects can be expected according to a member including a multilayer thin film configured as described above, a method of manufacturing the same, and an electronic product including the same.

First, it may be implemented so that a surface of a plastic object and an exterior of the product have a metal sense by ensuring that the multilayer thin film is formed on the plastic object or a surface of a housing of the electronic product.

Because a metal layer may be deposited on an object having a curved shape, it is possible to implement a deep metal sense on the product having more various shapes.

The metal sense is implemented by a pure dry method using a sputtering manufacturing device, and thus the multilayer thin film can be environmentally-friendly formed.

Further, the multilayer thin film can be formed on an uneven surface of the plastic object.

Although a few exemplary embodiments have been shown and described, it would be appreciated by those skilled in the art that changes may be made in these exemplary embodiments without departing from the principles and spirit of the invention, the scope of which is defined in the claims and their equivalents.

What is claimed is:

1. A method of manufacturing a multilayer thin film, the method comprising:
plasma-treating a surface of a plastic object;
depositing a reflective metal layer on the surface of the plastic object; and
depositing a transparent ceramic layer on the reflective metal layer.

2. The method according to claim 1, wherein the depositing the reflective metal layer on the surface of the plastic object comprises:
providing a target sample including at least one selected from a group consisting of gold (Au), silver (Ag), aluminum (Al), chromium (Cr), titanium (Ti), and Tin (Sn) in a multilayer thin film manufacturing device; and
applying power from a power source to the multilayer thin film manufacturing device.

3. The method according to claim 1, wherein the depositing the transparent ceramic layer on the reflective metal layer comprises:
providing a target sample including at least one selected from a group consisting of aluminum (Al), chromium (Cr), titanium (Ti), and silicon (Si) in a multilayer thin film manufacturing device;
injecting a reaction gas including nitrogen (N₂) and oxygen (O₂) in the multilayer thin film manufacturing device; and
applying power from a power source to the multilayer thin film manufacturing device and reacting the target sample with the reaction gas.

4. The method according to claim 1, further comprising, after the plasma-treating the surface of the plastic object, depositing a hardness enhancement layer on the plastic object.

5. The method according to claim 4, wherein the depositing the hardness enhancement layer comprises:
depositing a first hardness enhancement layer including chromium (Cr) on the plastic object; and
depositing a second hardness enhancement layer including at least one selected from a group consisting of titanium nitride (TiN), chromium nitride (CrN), and aluminum nitride (AlN) on the first hardness enhancement layer.

6. A method of manufacturing a multilayer thin film, the method comprising:
modifying a surface of a plastic object using a plasma treatment;
depositing a first metal layer on the surface of the plastic object; and
depositing a second metal layer on the first metal layer, wherein the second metal layer has a refractive index that is smaller than a refractive index of the first metal layer.

7. The method according to claim 6, wherein the depositing the first metal layer on the surface of the plastic object comprises:
providing a metallic material including at least one component selected from a group consisting of aluminum (Al), chromium (Cr), titanium (Ti), and silicon (Si) in a multilayer thin film manufacturing device;
injecting at least one reaction gas selected from a group consisting of nitrogen (N₂) and oxygen (O₂) in the multilayer thin film manufacturing device; and
applying power from a power source to the multilayer thin film manufacturing device and reacting the metallic material with the reaction gas.

8. The method according to claim 7, wherein the power source includes at least one of a pulsed DC power source and a DC power source.

9. The method according to claim 6, wherein the depositing the second metal layer on the first metal layer comprises:
providing a metallic material including at least one selected from a group consisting of aluminum (Al), chromium (Cr), titanium (Ti), and silicon (Si) in a multilayer thin film manufacturing device; and
applying power from a power source to the multilayer thin film manufacturing device.

10. The method according to claim 9, wherein the power source includes at least one of a pulsed DC power source and a DC power source.

11. The method according to claim 6, further comprising depositing an adhesive layer on the surface of the plastic object after the modifying the surface of the plastic object using the plasma treatment, and before the depositing the first metal layer.

12. The method according to claim 6, further comprising depositing a protective layer on the second metal layer after the depositing the second metal layer on the first metal layer.

13. A plastic member comprising:
a plastic object;
a reflective metal layer coupled to the plastic object; and
a transparent ceramic layer coupled to the reflective metal layer.

14. The plastic member according to claim 13, wherein the reflective metal layer includes at least one selected from a group consisting of gold (Au), silver (Ag), aluminum (Al), chromium (Cr), titanium (Ti), and Tin (Sn).

15. The plastic member according to claim 13, wherein the transparent ceramic layer includes at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂).

16. The plastic member according to claim 13, further comprising a hardness enhancement layer interposed between the plastic object and the reflective metal layer.

17. The plastic member according to claim 16, wherein the hardness enhancement layer comprises:
a first hardness enhancement layer including chromium (Cr) and coupled to the plastic object; and
a second hardness enhancement layer including at least one selected from a group consisting of titanium nitride (TiN), chromium nitride (CrN), and aluminum nitride (AlN) and coupled to the first hardness enhancement layer.

18. A plastic member comprising:
a plastic object which is plasma treated;
a first metal layer deposited on the plastic object; and
a second metal layer deposited on the first metal layer and having a refractive index that is smaller than a refractive index of the first metal layer.

19. The plastic member according to claim 18, wherein the first metal layer includes at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂).

20. The plastic member according to claim 18, wherein the second metal layer includes at least one selected from a group consisting of aluminum (Al), chromium (Cr), titanium (Ti), and Tin (Sn).

21. The plastic member according to claim 18, further comprising:
an adhesive layer including at least one selected from a group consisting of aluminum (Al), chromium (Cr), titanium (Ti), tin (Sn), aluminum nitride (AlN), chromium nitride (CrN), titanium nitride (TiN), and tin nitride (Sn₃N₄),
wherein the adhesive layer is interposed between the plastic object and the first metal layer.

22. The plastic member according to claim 18, further comprising a protective layer including at least one selected from a group consisting of polytetrafluoroethylene (PTFE) and silicon oxide (SiO₂) on the second metal layer.

23. An electronic product comprising:
a housing; and
a multilayer thin film coupled to a surface of the housing,
wherein the multilayer thin film comprises:
a reflective metal layer coupled to the surface of the housing; and
a transparent ceramic layer coupled to the reflective metal layer.

24. The electronic product according to claim 23, wherein the housing includes an accessory of the housing.

25. The electronic product according to claim 23, wherein the reflective metal layer includes at least one selected from a group consisting of gold (Au), silver (Ag), aluminum (Al), chromium (Cr), titanium (Ti), and Tin (Sn).

26. The electronic product according to claim 23, wherein the transparent ceramic layer includes at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂).

27. The electronic product according to claim 23, further comprising a hardness enhancement layer interposed between the surface of the housing and the reflective metal layer.

28. The plastic member according to claim 27, wherein the hardness enhancement layer comprises:
a first hardness enhancement layer including chromium (Cr) and coupled to the surface of the housing; and
a second hardness enhancement layer including at least one selected from a group consisting of titanium nitride (TiN), chromium nitride (CrN), and aluminum nitride (AlN) and coupled to the first hardness enhancement layer.

29. An electronic product comprising:
a housing including a plastic object; and
a multilayer thin film coupled to a surface of the housing,
wherein the multilayer thin film comprises:
a first metal layer coupled to the surface of the housing; and
a second metal layer coupled to the first metal layer and having a refractive index that is smaller than a refractive index of the first metal layer.

30. The electronic product according to claim 29, wherein the housing includes an accessory of the housing.

31. The electronic product according to claim 29, wherein the first metal layer includes at least one selected from a group consisting of aluminum nitride (AlN), chromium nitride (CrN), titanium nitride (TiN), silicon nitride (Si₃N₄), aluminum oxide (Al₂O₃), chromium oxide (Cr₂O₃), titanium oxide (Ti₂O₃), and silicon oxide (SiO₂).

32. The electronic product according to claim 29, wherein the second metal layer includes at least one selected from a group consisting of aluminum (Al), chromium (Cr), titanium (Ti), and Tin (Sn).

33. The electronic product according to claim 29, wherein the multilayer thin film further comprises:
an adhesive layer including at least one selected from a group consisting of aluminum (Al), chromium (Cr), titanium (Ti), tin (Sn), aluminum nitride (AlN), chromium nitride (CrN), titanium nitride (TiN), and tin nitride (Sn₃N₄), and
the adhesive layer is interposed between the surface of the plastic object and the first metal layer.

34. The plastic member according to claim 29, wherein the multilayer thin film further comprises a protective layer including at least one selected from a group consisting of PTFE and silicon oxide (SiO₂) on the second metal layer.
